(19) United States
(12) Patent Application Publication
(10) Pub. No.: US 2008/0070405 A1
(43) Pub. Date: Mar. 20, 2008

(54) Methods of forming metal wiring layers for semiconductor devices

(76) Inventors: Jae-hwa Park, Gyeonggi-do (KR); Gil-heyun Choi, Gyeonggi-do (KR); Jong-myeong Lee, Gyeonggi-do (KR); Hee-sook Park, Seoul (KR)

Correspondence Address: MYERS BIGEL SIBLEY & SAJOVEC, PO BOX 37428, RALEIGH, NC, 27627, US

(21) Appl. No.: 11/800,996

(22) Filed: May 8, 2007

Related U.S. Application Data
(63) Continuation-in-part of application No. 11/033,781, filed on Jan. 12, 2005.
(63) Continuation-in-part of application No. 11/095,006, filed on Mar. 31, 2005.
Application No. 11/095,006 is a continuation-in-part of application No. 10/373,368, filed on Feb. 24, 2003, now Pat. No. 6,955,983.

(30) Foreign Application Priority Data
Jan. 14, 2004 (KR) 2004-2666
May 30, 2002 (KR) 2002-0030294

(51) Int. Cl. H01L 21/44

(52) U.S. Cl. 438/656; 257/E21.476

(57) ABSTRACT

A method of forming a conductive plug for an integrated circuit device may include forming an insulating layer on an integrated circuit substrate with the insulating layer having a surface opposite the substrate and a recess therein. A titanium (Ti) layer may be formed on sidewalls of the recess and on the surface of the insulating layer opposite the substrate. After forming the titanium (Ti) layer, a reaction reducing layer may be formed on portions of the titanium layer on the surface of the insulating layer opposite the substrate by at least one of ionized physical vapour deposition (iPVD) and/or nitriding a portion of the titanium layer, and the reaction reducing layer may include a material other than titanium. After forming the reaction reducing layer, a TiN layer may be formed on the reaction reducing layer and on sidewalls of the recess in the insulating layer using metal organic chemical vapour deposition (MOCVD). After forming the TiN layer, a conductive plug may be formed on the TiN layer in the recess in the insulating layer.

### RELATED APPLICATIONS

This application claims the benefit of priority as a continuation-in-part (CIP) of U.S. application Ser. No. 11/033,781 (currently pending), filed Jan. 12, 2005, which claims the benefit of priority of Korean Patent Application No. 2004-2666, filed on Jan. 14, 2004, in the Korean Intellectual Property Office. This application also claims the benefit of priority as a continuation-in-part (CIP) of U.S. application Ser. No. 11/095,006 (currently pending), filed Mar. 31, 2005, which claims the benefit of priority as a divisional of U.S. application Ser. No. 10/373,368 (now issued as U.S. Pat. No. 6,955,983), filed Feb. 24, 2003, which claims the benefit of priority of Korean Patent Application No. 2002-0030294, filed on May 30, 2002. The disclosures of all of the above referenced U.S. and Korean patent applications are hereby incorporated herein in their entirety by reference.

### FIELD OF THE INVENTION

The present invention relates to semiconductor integrated circuits, and more particularly, to methods of forming metal wiring layers for semiconductor integrated circuits.

### BACKGROUND

As integration densities of semiconductor devices increase, circuits having multi-layered metal wiring layers may be desired. Since the metal wiring layer transmits an electrical signal, a relatively low electrical resistance may be desired. In addition, relatively low cost and high reliability may be desired.

Also, as semiconductor devices become more highly integrated, widths and thicknesses of metal wiring layers and sizes of contact holes may decrease. As feature sizes of a semiconductor device decrease, widths of circuit lines may decrease, patterns of semiconductor devices may be micro-sized, and/or forming metal wiring layers by etching a metal film may be more difficult. In addition, it may be desirable to reduce a thermal budget in a backend process for a highly integrated semiconductor device manufacturing process. If the thermal budget in the backend process increases, parameters affecting electrical characteristics of the semiconductor device, in addition to capacitor characteristics, may deteriorate. In particular, a reduced equivalent oxide film (Toxeq) thickness and an increased capacitance may be provided for a DRAM capacitor to accommodate reduced design rules and/or refresh characteristics. Metal/insulator/polysilicon (MIS) and/or metal/insulator/metal (MIM) type capacitors have thus been used. In particular, research has been conducted with respect to TiN/insulator/polysilicon (TIS) and/or TiN/insulator/TiN (TIT) type capacitors. To form these capacitors, however, forming a wiring layer may include forming a barrier metal film for a contact plug at a relatively low temperature. Also, when a NiSi substrate is used, the barrier metal layer may need to be formed at a temperature below 450° C.

In a conventional process of forming a barrier metal layer using TiCI₄ as a basic source gas, a Ti/TiN barrier film may be formed using chemical vapor deposition (CVD) at a temperature of 650° C. or greater. When a MIS or MIM type capacitor is employed, however, a high temperature process of forming a barrier metal layer may not be appropriate.

In place of a conventional high temperature process, another conventional technology may be applied to form a barrier metal film at a relatively low temperature. In the low temperature process, a Ti film may first be formed using ionized physical vapor deposition (iPVD), and a TiN film may be formed using metal organic chemical vapor deposition (MOCVD). A Ti film formed using iPVD may be referred to as an iPVD-Ti film, and a TiN film formed using MOCVD may be referred to as a MOCVD-TiN film. The MOCVD-TiN film may provide relatively good step coverage, but a density thereof may be relatively low. Accordingly, the use of an iPVD-Ti film and a MOCVD-TiN film as barrier metal layers may cause defects. More particularly, when a tungsten layer is etched back to form a tungsten (W) plug, pitting may occur in the MOCVD-TiN film due to overetching. As a result, portions of the Ti film, which are not protected by the pitted MOCVD-TiN film formed thereon, may be damaged by fluorine (F) radicals generated when the tungsten film is etched back. Moreover, in a subsequent process of forming an aluminum (Al) wiring layer, Al may react with carbon (C) in the MOCVD-TiN film, at damaged portions of the Ti film. As a result, an F-stuffed Al—Ti—C layer, instead of a stable Al₃Ti layer, may be undesirably formed, thereby causing defects.

MOCVD-TiN films have been treated using plasma or using rapid thermal nitridation (RTN) to improve the density of the MOCVD-TiN film. However, it may be difficult to completely prevent occurrence of defects in the Ti film. Meanwhile, a tungsten (W) plug can be formed using chemical mechanical polishing (CMP), instead of using etch-back, to reduce the formation of pitting in the MOCVD-TiN film. However, a CMP process may raise manufacturing costs.

### SUMMARY

According to embodiments of the present invention, methods of forming a conductive plug for an integrated circuit device may include forming an insulating layer on an integrated circuit substrate with the insulating layer having a surface opposite the substrate and a recess therein. A titanium (Ti) layer may be formed on sidewalls of the recess and on the surface of the insulating layer opposite the substrate. After forming the titanium layer (Ti), a reaction reducing layer may be formed on portions of the titanium (Ti) layer on the surface of the insulating layer opposite the substrate by at least one of ionized physical vapor deposition (iPVD) and/or nitriding a portion of the titanium layer, and the reaction reducing layer may include a material other than titanium. After forming the reaction reducing layer, a TiN layer may be formed on the reaction reducing layer and on sidewalls of the recess in the insulating layer using metal organic chemical vapor deposition (MOCVD). After forming the TiN layer, a conductive plug may be formed on the TiN layer in the recess in the insulating layer. More particularly, the reaction reducing layer may be a TiN layer.

Forming the reaction reducing layer may include nitriding a portion of the titanium layer using a plasma treatment in an atmosphere including nitrogen. Moreover, the atmosphere including nitrogen may include at least one of H₂/N₂ and/or NH₃, and forming the reaction reducing layer may include forming the reaction reducing layer at a temperature in the range of about 380 degrees C. to about 400 degrees C. In addition, the reaction reducing layer and the TiN layer may be formed in situ in a same process chamber.

The reaction reducing layer may include a TiN layer, and the reaction reducing layer may be formed using iPVD at a temperature in the range of about 150 degrees C. to about 250 degrees C. Moreover, the titanium layer and the reaction reducing layer may be formed in situ by iPVD in a same process chamber. The reaction reducing layer may have a thickness in the range of about 50 Angstroms to about 100 Angstroms, the TiN layer may be formed at a temperature in the range of about 380 degrees C. to about 400 degrees C., and the TiN layer may have thickness in the range of about 50 Angstroms to about 150 Angstroms.

Forming the conductive plug may include forming a conductive layer on the TiN layer and in the recess, and etching the conductive layer back to expose the surface of the insulating layer opposite the substrate while maintaining the conductive layer in the recess. Moreover, the conductive layer may include tungsten.

In addition, a wiring layer may be formed on the conductive plug and on the surface of the insulating layer opposite the substrate, and the wiring layer may include aluminum and/or an aluminum alloy. The recess may include a contact hole through the insulating layer exposing a conductive region of the integrated circuit substrate, and/or the recess may include a trench having a depth that is less than a thickness of the insulating layer.

The titanium layer may be formed using iPVD, and the titanium layer may be formed at a temperature in the range of about 150 degrees C. to about 250 degrees C. Moreover, forming the titanium layer may include forming the titanium layer on a bottom surface of the recess with portions of the titanium layer on the bottom surface of the recess having a thickness in the range of approximately 50 Angstroms to about 100 Angstroms. In addition, the reaction reducing layer may be formed on portions of the titanium layer on sidewalls of the recess.

Embodiments of the present invention may provide methods of forming a metal wiring layer of a semiconductor device that can be performed at relatively low temperatures to reduce a thermal budget. Further, when a metal layer is etched back to form a contact plug, damage to a barrier film can be reduced without significantly increasing processing costs. In addition, improved contact plug filling characteristics may be obtained, thereby providing a relatively stable metal wiring layer.

According to some embodiments of the present invention, a method of forming a metal wiring layer of a semiconductor device may include forming an insulating layer pattern on a substrate, wherein the insulating layer pattern has side walls and a top surface, and wherein the side walls constitute an inner wall of a recess region. A Ti film may be formed on the inner wall of the recess region and the top surface of the insulating layer pattern using ionized physical vapor deposition (iPVD). A reaction reducing layer may be formed on a portion of the Ti film covering the top surface of the insulating layer pattern to protect the Ti film. A TiN film may be formed inside the recess region and over the top surface of the insulating layer pattern using metal organic chemical vapor deposition (MOCVD) to cover the reaction reducing layer. A conducting plug may be formed on the TiN film to fill the recess region.

Forming the reaction reducing layer may include nitriding a portion of the Ti film using a plasma treatment under a N-containing atmosphere. More particularly, the reaction reducing layer may be formed under a H₂/N₂ plasma atmosphere or a NH₃ plasma atmosphere. In addition the TiN film and the reaction reducing layer may be formed in situ in one chamber.

The reaction reducing layer may include a TiN film formed using iPVD. The reaction reducing layer and the Ti film may be formed in situ in one chamber.

To form the conducting plug, a conducting layer may first be formed on the TiN film. Next, the conducting layer may be etched back over the top surface of the insulating layer pattern until the TiN film is exposed.

A wiring layer may be further formed on the conducting plug and over the insulating layer pattern. The wiring layer may include a layer of Al or an Al alloy.

According to other embodiments of the present invention, a barrier film may include a iPVD-Ti film and a MOCVD-TiN film, and a reaction reducing layer may be formed on the iPVD-Ti film. Thus, when a conducting layer, such as a tungsten film, is etched back to form a conducting plug, an F stuffing phenomenon can be reduced in the iPVD-Ti film even when pitting occurs. In addition, when an Al wiring layer or an Al alloy wiring layer is formed on the conducting plug using a reflow process, formation of undesired reaction products, such as a F-stuffed Al—Ti—C layer or a Ti—F—Al reaction product, can be reduced. Accordingly, in a process of forming the barrier film including the iPVD-Ti film and the MOCVD-TiN film (which may be suitable to reduce thermal budget in a process of forming a metal wiring layer) damage to the barrier film can be reduced without using an additional chamber and/or at a relatively low manufacturing cost. Therefore, a stable metal wiring layer can be implemented.

### BRIEF DESCRIPTION OF THE DRAWINGS

FIGS. 1A through 1F are cross-sectional views illustrating steps of forming a metal wiring layer of a semiconductor device according to first embodiments of the present invention.

FIGS. 2A through 2F are cross-sectional views illustrating steps of forming a metal wiring layer of a semiconductor device according to second embodiments of the present invention.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

In the drawings, the thickness of layers and regions are exaggerated for clarity. It will also be understood that when an element such as a layer, region or substrate is referred to as being on another element, it can be directly on the other element or intervening elements may also be present. In contrast, if an element such as a layer, region or substrate is referred to as being directly on another element, then no other intervening elements are present. As used herein, the term and/or includes any and all combinations of one or more of the associated listed items.

Furthermore, relative terms, such as beneath, upper, and/or lower may be used herein to describe one element's relationship to another element as illustrated in the figures. It will be understood that relative terms are intended to encompass different orientations of the device in addition to the orientation depicted in the figures. For example, if the device in one of the figures is turned over, elements described as below other elements would then be oriented above the other elements. The exemplary term below, can therefore, encompasses both an orientation of above and below.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second region, layer or section could be termed a first region, layer or section without departing from the teachings of the present invention. Like numbers refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

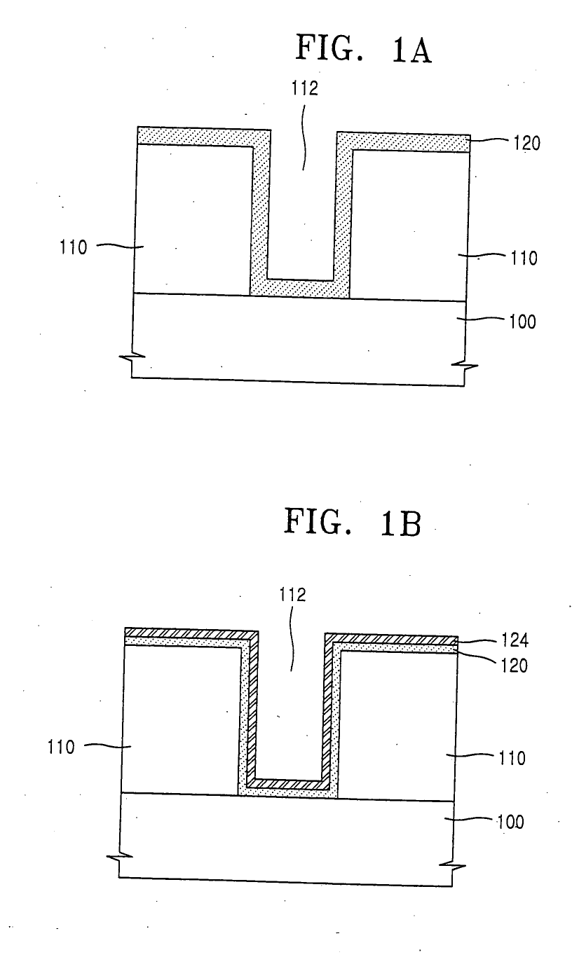

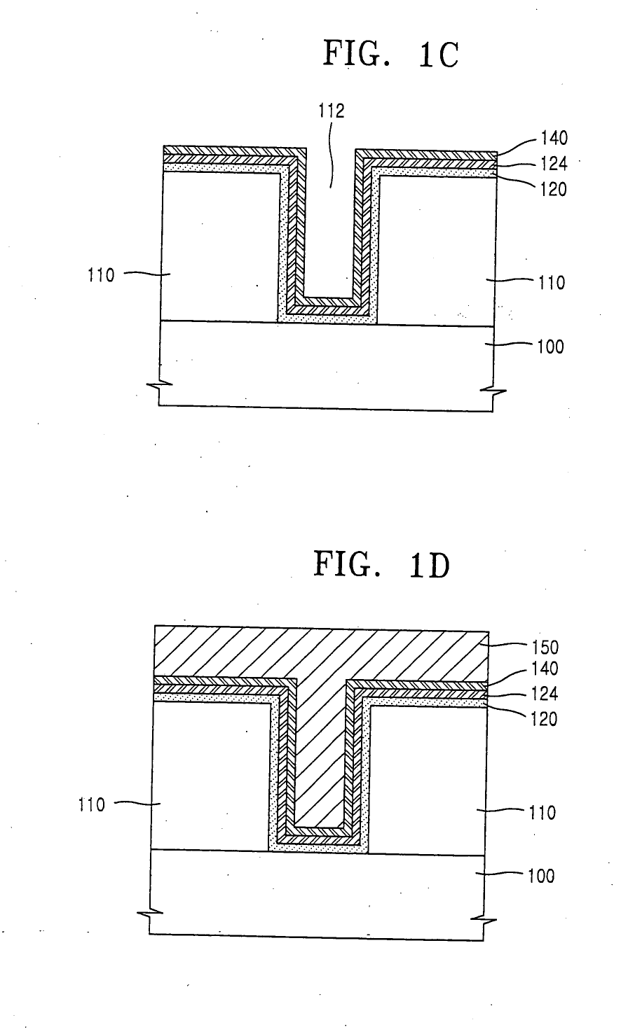

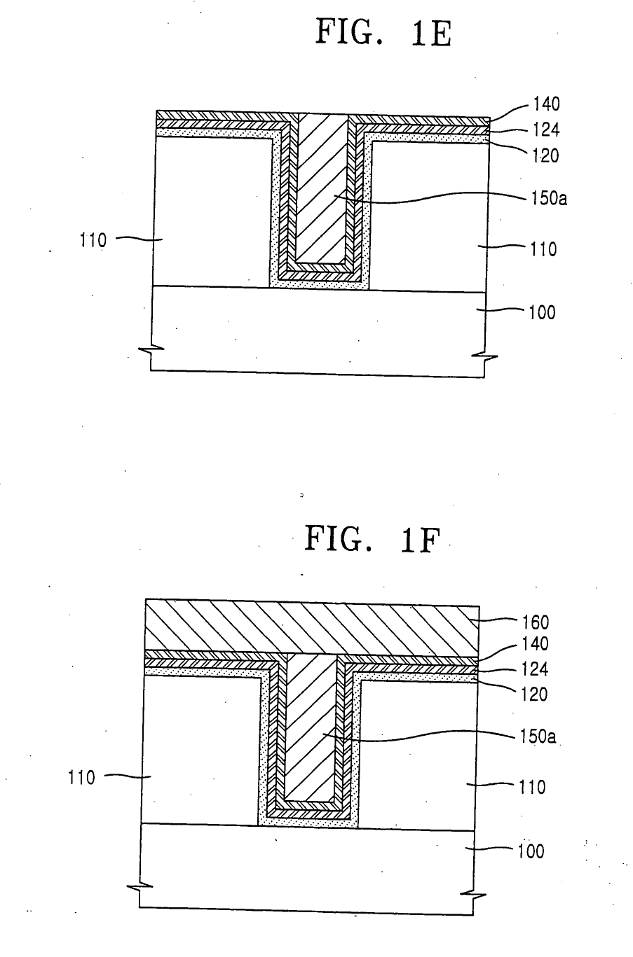

FIGS. 1A through 1F are cross-sectional views illustrating steps of forming a metal wiring layer of a semiconductor device according to first embodiments of the present invention. Referring to FIG. 1A, an insulating layer pattern 110 is formed on a semiconductor substrate 100. The insulating layer pattern 110 has side walls and a top surface. The side walls of the insulating layer pattern 110 constitute inner walls of a recess 112. The insulating layer pattern 110 may be an interlayer insulating layer formed to separate unit devices, and/or to separate layers of multi-layered wiring. The recess 112 may be a contact hole, which exposes a conducting region (not shown) of the semiconductor substrate 100 as shown in FIG. 1A. Alternatively, the recess 112 may be a trench having a depth that is less than the thickness of the insulating layer pattern 110.

A titanium (Ti) film 120 may be formed on the inner wall of the recess 112 and the top surface of the insulating layer pattern 110 using ionized physical vapor deposition (iPVD). The Ti film 120 may be formed at a temperature in the range of about 150° C. to about 250° C. A portion of the Ti film 120 on a bottom surface of the recess 112, may have a thickness in the range of about 50 Angstroms to about 100 Angstroms, and more particularly in the range of about 70 Angstroms to about 80 Angstroms.

Referring to FIG. 1B, a reaction reducing layer 124 may be formed on at least a portion of the Ti film 120, which covers the top surface of the insulating layer pattern 110, to protect the Ti film 120. The reaction reducing layer 124 may be formed to protect the Ti film 120 and to reduce formation of defect-causing reaction products due to penetration of impurities into the Ti film 120. Although the reaction reducing layer 124 is illustrated in FIG. 1B as being formed on the entire top surface of the Ti film 120, embodiments of the present invention are not limited thereto. That is, the reaction reducing layer 124 may be formed only on portions of the Ti film 120 covering the top surface of the insulating layer pattern 110.

The reaction reducing layer 124 may be formed by nitriding a top portion of the Ti film 120 to a predetermined thickness. In particular, the Ti film 120 may be subject to a plasma treatment under a N-containing atmosphere, so that the top portion of the Ti film 120 is nitrided. The reaction reducing layer 124 may be formed in a metal organic chemical vapor deposition (MOCVD) chamber. The reaction reducing layer 124 may be formed by nitriding a top portion of the Ti film 120 at a temperature in the range of about 380° C. to about 400° C. under a H₂/N₂ plasma atmosphere or under a NH₃ plasma atmosphere. The plasma treatment may be performed at a power in the range of about 300 Watts to about 1000 Watts.

Referring to FIG. 1C, a titanium nitride (TiN) film 140 may be formed inside the recess 112 and over the top surface of the insulating layer pattern 110 using MOCVD to cover the reaction reducing layer 124. Since the use of the MOCVD may provide relatively good step coverage, a thickness of the TiN film 140 formed using MOCVD may be relatively constant both inside the recess 112 and over the top surface of the insulating layer pattern 110. When the TiN film 140 is formed, an organometallic compound can be used as a Ti precursor. Examples of organometallic compounds include tetrakis(dimethylamino)titanium (TDMAT), tetrakis(diethylamino)titanium(TDEAT), and/or TiCI₄.

The TiN film 140 may be formed in situ in one process chamber where the reaction reducing layer 124 is formed, after the reaction reducing layer 124 is formed. The TiN film 140 may be formed to a thickness in the range of about 50 Angstroms to about 150 Angstroms and more particularly, to a thickness of about 100 Angstroms. The TiN film 140 may be formed at a temperature in the range of about 380° C. to about 400° C. in a MOCVD process chamber.

Referring to FIG. 1D, a conducting layer 150 may be formed on the TiN film 140 to a thickness that is sufficient to fill inside the recess 112 and to cover the top surface of the insulating layer pattern 110. The conducting layer 150 may include a layer of a metal such as tungsten (W). A tungsten film providing the conducting layer 150 may be formed using chemical vapour deposition (CVD) or atomic layer deposition (ALD). The tungsten film can be deposited at a relatively low temperature in the range of about 200° C. to about 400° C.

Referring to FIG. 1E, the conducting layer 150 may be etched back over the top surface of the insulating layer pattern 110 until the TiN film 140 is exposed, to form a conducting plug 150a filling the recess 112. When the conducting layer 150 is etched back, a pitting phenomenon may be observed in the TiN film 140. However, even if pitting occurs, the Ti film 120 formed on the top surface of the insulating layer pattern 110 may be protected by the reaction reducing layer 124, thereby reducing an F stuffing phenomenon in the Ti film 120. An undesired reaction between Ti and F can thus be reduced in the Ti film 120.

Referring to FIG. 1F, a wiring layer 160 may be formed on a top surface of the conducting plug 150a, and a top surface of the TiN film 140 covering the top surface of the insulating layer pattern 110. The wiring layer 160 may include a layer of Al and/or an Al alloy.

The wiring layer 160 may be formed to a thickness in the range of about 400 Angstroms to about 1000 Angstroms. The wiring layer 160 may be deposited at a relatively low temperature in the range of about 90° C. to about 400° C. The wiring layer 160 including Al and/or an Al alloy can be formed using various methods. For example, an Al film or an Al alloy film may be first formed using physical vapor deposition (PVD) and then a reflow process may be performed thereon using a thermal treatment. In an alternative, an Al film may be formed using MOCVD, wherein a precursor of an organometallic compound is used as an Al source. Next, PVD may be further performed to form an Al film and/or an Al alloy film thereon.

Even when an Al reflow process is used to form the wiring layer 160, the Ti film 120 may be protected by the reaction reducing layer 124. As a result, generation of undesired reaction products (such as an F-stuffed Al—Ti—C layer and/or a Ti—F—Al reaction product) are not generated in the Ti film 120.

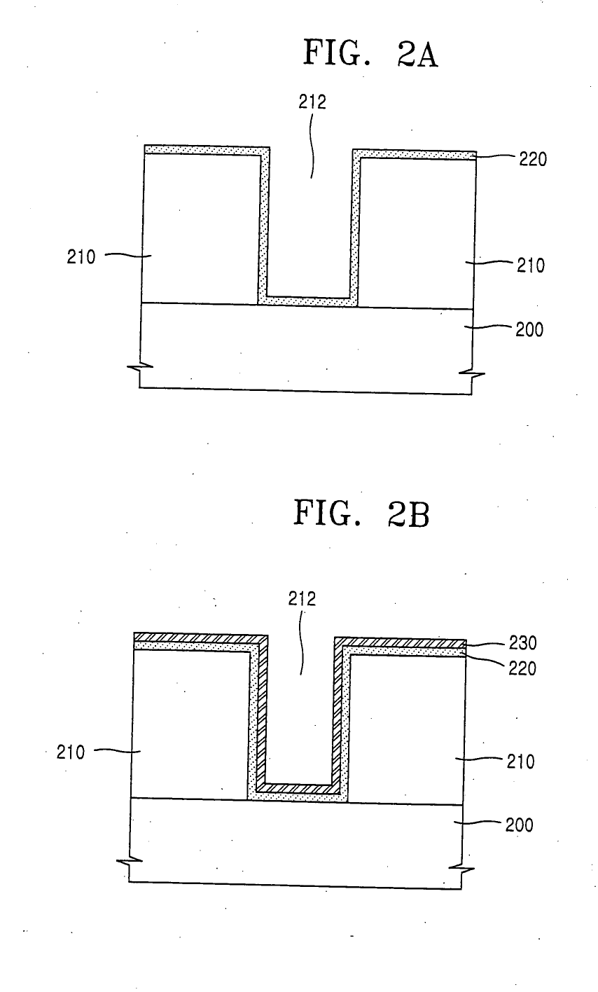

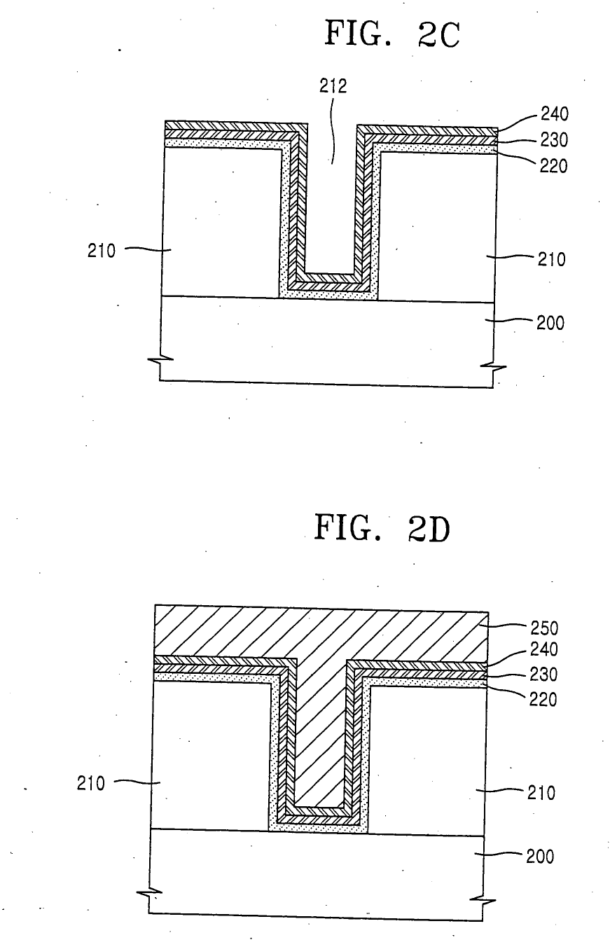

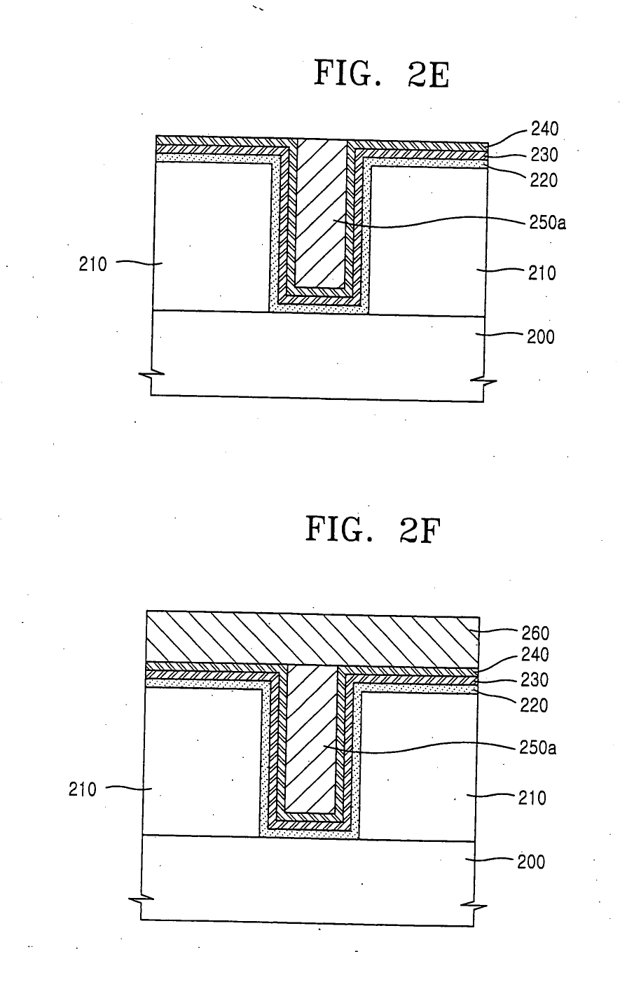

FIGS. 2A through 2F are cross-sectional views illustrating steps of forming a metal wiring layer of a semiconductor device according to second embodiments of the present invention. In FIGS. 2B through 2F, a reaction reducing layer 230 may include a TiN film formed using iPVD. Hereinafter, further details thereof will be described.

Referring to FIG. 2A, an insulating layer pattern 210 (which has side walls and a top surface) is formed on a semiconductor substrate 200 as discussed above with respect to the insulating layer pattern 110 of FIG. 1A. The side walls of the insulating layer pattern 210 provide inner walls of a recess 212. A Ti film 220 is formed on the insulating layer pattern 210 using iPVD.

Referring to FIG. 2B, a reaction reducing layer 230 is formed on at least portions of the Ti film 220 covering the top surface of the insulating layer pattern 210, to protect the Ti film 220. The reaction reducing layer 230 is formed to protect the Ti film 220 and/or to reduce formation of defect-causing reaction products by penetration of impurities into the Ti film 220. Although FIG. 2B shows the reaction reducing layer 230 formed on the entire top surface of the Ti film 220, embodiments of the present invention are not limited thereto. That is, the reaction reducing layer 230 may be formed only on portions of the Ti film 220 covering the top surface of the insulating layer pattern 210.

The reaction reducing layer 230 may be a layer of a TiN film formed using iPVD. The reaction reducing layer 230 may be formed to a thickness in the range of about 50 Angstroms to about 100 Angstroms over the insulating layer pattern 210. The reaction reducing layer 230 and the Ti film 220 may be formed in-situ in one chamber. The reaction reducing layer 230 may be formed at a temperature in the range of about 150° C. to about 250° C.

Referring to FIG. 2C, a TiN film 240 may be formed inside the recess 212 and over the top surface of the insulating layer pattern 210 using MOCVD to cover the reaction reducing layer 230 as discussed above with respect to the TiN film 140 of FIG. 2C.

Referring to FIG. 2D, a conducting layer 250 may be formed on the TiN film 240 to a thickness sufficient to fill the recess 212 and to cover the top surface of the insulating layer pattern 210 as discussed above with respect to the conducting layer 150 of FIG. 2D.

Referring to FIG. 2E, the conducting layer 250 may be etched back over the top surface of the insulting film pattern 210 until the TiN film 240 is exposed, so that a conducting plug 250a filling the recess 222 is formed. When the conducting layer 250 is etched back, the pitting phenomenon may be observed in the TiN film 240. However, the Ti film 220 may be protected by the reaction reducing layer 230, so that an F stuffing phenomenon can be reduced in the Ti film 220. Thus, an undesired reaction between Ti and F can be reduced in the Ti film 220.

Referring to FIG. 2F, a wiring layer 260 of Al and/or an Al alloy, may be formed on a top surface of the conducting plug 250a, and on a top surface of the TiN film 240 covering the top surface of the insulating layer pattern 210.

Even if an Al reflow process is performed to form the wiring layer 260, the Ti film 220 may be protected by the reaction reducing layer 230. As a result, generation of undesired reaction products (such as an F-stuffed Al—Ti—C layer and/or a Ti—F—Al reaction product) may be reduced in the Ti film 220.

When forming a metal wiring layer of a semiconductor-device according to embodiments of the present invention, a conducting plug may be formed on a barrier film including an iPVD-Ti film and a MOCVD-TiN film. A reaction reducing layer may be further formed in two manners: first, a surface of the iPVD-Ti film may be nitrided under a plasma atmosphere before the MOCVD-TiN film may be formed; second, a TiN film is formed on the iPVD-Ti film using iPVD. Since the iPVD-Ti film is protected by the reaction reducing layer formed thereon, an F stuffing phenomenon in the iPVD-Ti can be reduced even if a pitting phenomenon occurs in the MOCVD-TiN film when a conducting layer (such as a tungsten film) is over-etched to form the conducting plug. In addition, when an Al wiring layer and/or an Al alloy wiring layer is formed on the conducting plug using a reflow process, the reaction reducing layer may reduce formation of undesired reaction products, such as an F-stuffed Al—Ti—C layer and/or a Ti—F—Al reaction product.

According to embodiments of the present invention, a barrier film including an iPVD-Ti film and a MOCVD-TiN film (which can appropriately reduce thermal budget when forming a metal wiring layer) can be protected from damage without using an additional chamber. Moreover, even when a tungsten film is etched back, damage to the barrier film can be reduced. As a result, there is no need to perform a CMP process, and manufacturing costs can thus be reduced. In addition, contact filling characteristics of metal for a contact plug can be improved (even when a micro-sized contact is formed according to sub-micron design rules) because a thickness margin of a TiN thin film can be increased. Thus, a stable wiring layer can be formed on the contact plug.

While the present invention has been particularly shown and described with reference to embodiments thereof, it will be understood by those skilled in the art that various changes in form and details may be made therein without departing from the spirit and scope of the invention as defined by the appended claims and their equivalents.

What is claimed is:

1. A method of forming a conductive plug for an integrated circuit device, the method comprising:
forming an insulating layer on an integrated circuit substrate, the insulating layer having a surface opposite the substrate and a recess therein;
forming a titanium (Ti) layer on sidewalls of the recess and on the surface of the insulating layer opposite the substrate;
after forming the titanium layer (Ti), forming a reaction reducing layer on portions of the titanium (Ti) layer on the surface of the insulating layer opposite the substrate by at least one of ionized physical vapor deposition (iPVD) and/or nitriding a portion of the titanium layer wherein the reaction reducing layer comprises a material other than titanium;
after forming the reaction reducing layer, forming a TiN layer on the reaction reducing layer and on sidewalls of the recess in the insulating layer using metal organic chemical vapor deposition (MOCVD); and
after forming the TiN layer, forming a conductive plug on the TiN layer in the recess in the insulating layer.

2. A method according to claim 1 wherein the reaction reducing layer comprises a TiN layer.

3. A method according to claim 1 wherein forming the reaction reducing layer comprises nitriding a portion of the titanium layer using a plasma treatment in an atmosphere including nitrogen.

4. A method according to claim 3 wherein the atmosphere including nitrogen includes at least one of H₂/N₂ and/or NH₃.

5. A method according to claim 3 wherein forming the reaction reducing layer comprises forming the reaction reducing layer at a temperature in the range of about 380 degrees C. to about 400 degrees C.

6. A method according to claim 3 wherein the reaction reducing layer and the TiN layer are formed in situ in a same process chamber.

7. A method according to claim 1 wherein the reaction reducing layer comprises a TiN layer and wherein forming the reaction reducing layer comprises forming the reaction reducing layer by iPVD.

8. A method according to claim 7 wherein forming the reaction reducing layer comprises for the reaction reducing layer by iPVD at a temperature in the range of about 150 degrees C. to about 250 degrees C.

9. A method according to claim 7 wherein the titanium layer and the reaction reducing layer are formed in situ by iPVD in a same process chamber.

10. A method according to claim 1 wherein the reaction reducing layer has a thickness in the range of about 50 Angstroms to about 100 Angstroms.

11. A method according to claim 1 wherein forming the TiN layer comprises forming the TiN layer at a temperature in the range of about 380 degrees C. to about 400 degrees C.

12. A method according to claim 1 wherein forming TiN layer comprises forming the TiN layer having thickness in the range of about 50 Angstroms to about 150 Angstroms.

13. A method according to claim 1 wherein forming the conductive plug comprises,
forming a conductive layer on the TiN layer and in the recess; and
etching the conductive layer back to expose the surface of the insulating layer opposite the substrate while maintaining the conductive layer in the recess.

14. A method according to claim 13 wherein the conductive layer-comprises tungsten.

15. A method according to claim 1 further comprising:
forming a wiring layer on the conductive plug and on the surface of the insulating layer opposite the substrate.

16. A method according to claim 15 wherein the wiring layer comprises aluminum and/or an aluminum alloy.

17. A method according to claim 1 wherein the recess comprises a contact hole through the insulating layer exposing a conductive region of the integrated circuit substrate.

18. A method according to claim 1 wherein the recess comprises a trench having a depth that is less than a thickness of the insulating layer.

19. A method according to claim 1 wherein forming the titanium layer comprises forming the titanium layer by iPVD.

20. A method according to claim 1 wherein forming the titanium layer comprises forming the titanium layer at a temperature in the range of about 150 degrees C. to about 250 degrees C.

21. A method according to claim 1 wherein forming the titanium layer further comprises forming the titanium layer on a bottom surface of the recess with portions of the titanium layer on the bottom surface of the recess having a thickness in the range of approximately 50 Angstroms to about 100 Angstroms.

22. A method according to claim 1 wherein forming the reaction reducing layer further comprises forming the reaction reducing layer on portions of the titanium layer on sidewalls of the recess.

23. A method of forming a metal wiring layer of a semiconductor device comprising:
forming an insulating layer pattern on a substrate, the insulating layer pattern having side walls and a top surface, wherein the side walls constitute an inner wall of a recess region;
forming a Ti film on the inner wall of the recess region and the top surface of the insulating layer pattern using ionized physical vapor deposition (iPVD);
forming a reaction reducing layer on a portion of the Ti film covering the top surface of the insulating layer pattern in order to protect the Ti film;
forming a TiN film inside the recess region and over the top surface of the insulating layer pattern using metal organic chemical vapor deposition (MOCVD) in order to cover the reaction reducing layer; and
forming a conducting plug on the TiN film in order to fill inside the recess region.
